(19) United States
(12) Patent Application Publication
(10) Pub. No.: US 2015/0035621 A1
(43) Pub. Date: Feb. 5, 2015

(54) COMPOSITE ELECTRONIC COMPONENT

(71) Applicant: Samsung Electro-Mechanics Co., Ltd, Suwon-Si (KR)

(72) Inventors: Young Ghyu AHN, Suwon-Si (KR); Sang Soo PARK, Suwon-Si (KR); Min Cheol PARK, Suwon-Si (KR); Byoung Hwa LEE, Suwon-Si (KR)

(73) Assignee: Samsung Electro-Mechanics Co., Ltd

(21) Appl. No.: 14/447,207

(22) Filed: Jul. 30, 2014

(30) Foreign Application Priority Data
Jul. 30, 2013 (KR) 10-2013-0090010

(51) Int. Cl. H03H 7/01

(52) U.S. Cl. CPC H03H 7/0138; H03H 7/0115
USPC 333/184

(57) ABSTRACT

A composite electronic component includes an input terminal portion receiving power converted by a power management unit, a power stabilizing unit stabilizing the power and including a composite body including a capacitor and a coil and having a hexahedral shape, the capacitor including a plurality of dielectric layers, internal electrodes disposed so as to face each other with a respective dielectric layer interposed therebetween, and capacitor electrodes electrically connected to the internal electrodes, and the coil being wound so as to encompass the capacitor and being buried in a magnetic material portion, and an output terminal portion supplying the stabilized power.

### CROSS-REFERENCE TO RELATED APPLICATION

This application claims the benefit of Korean Patent Application No. 10-2013-0090010 filed on Jul. 30, 2013, with the Korean Intellectual Property Office, the disclosure of which is incorporated herein by reference.

### BACKGROUND

The present disclosure relates a composite electronic component including a plurality of passive devices.

In accordance with a recent demand for thinness and lightness of electronic apparatuses and improvement of performance of the electronic apparatuses, it has been demanded for the electronic apparatuses to have a significantly decreased size and various functions.

These electronic apparatuses include a power semiconductor-based power management integrated circuit (PMIC) serving to efficiently control and manage a limited battery resource in order to satisfy various service requirements.

However, as the electronic apparatuses include various functions, the number of direct current (DC) to DC converters included in the PMIC has increased. In addition, the number of passive devices that should be included in a power input terminal and a power output terminal of the PMIC has also increased.

In this case, an area in which components are disposed in the electronic apparatuses increases, which may limit miniaturization of the electronic apparatuses.

In addition, a high level of noise may occur due to a PMIC and wiring patterns of peripheral circuits of the PMIC.

### RELATED ART DOCUMENT

Korean Patent Laid-Open Publication No. 2003-0014586

### SUMMARY

Some embodiments of the present disclosure may provide a composite electronic component able to be mounted in a decreased area in a driving power supply system.

Some embodiments of the present disclosure may also provide a composite electronic component capable of suppressing the generation of noise in a driving power supply system.

According to some embodiments of the present disclosure, a composite electronic component may include: an input terminal portion receiving power converted by a power management unit; a power stabilizing unit stabilizing the power; and an output terminal portion supplying the stabilized power, wherein the power stabilizing unit includes: a coil having an air-core portion; and a capacitor disposed in the air-core portion.

The coil may be wound to encompass a first side surface, a first end surface, a second side surface, and a second end surface of the capacitor.

The coil may be wound to be parallel to a plane defined by a length direction and a width direction of the composite electronic component.

A winding center of the coil may be formed on a plane defined by a length direction and a width direction of the composite electronic component.

The coil may be electrically connected to the input terminal portion and the output terminal portion.

The capacitor may include: a plurality of dielectric layers; a plurality of internal electrodes disposed to face each other so as to have a respective dielectric layer interposed between the plurality of internal electrodes; and capacitor electrodes electrically connected to the internal electrodes.

The capacitor electrodes may be elongated in the width direction.

The capacitor electrodes may be elongated in the length direction.

The power stabilizing unit may decrease noise of the power.

According to some embodiments of the present disclosure, a composite electronic component may include: a composite body including a capacitor and a coil and having a hexahedral shape, the capacitor including a plurality of dielectric layers, internal electrodes disposed to face each other with a respective dielectric layer interposed between the internal electrodes, and capacitor electrodes electrically connected to the internal electrodes, and the coil being wound to encompass the capacitor and being buried in a magnetic material portion; an input terminal portion formed on a first end surface of the composite body and connected to one end of the coil; and an output terminal portion formed on a second end surface of the composite body and connected to the other end of the coil.

The capacitor electrodes may protrude from at least one of upper and lower surfaces of the composite body having the hexahedral shape.

According to some embodiments of the present disclosure, a composite electronic component may include: an input terminal portion receiving power converted by a power management unit; a power stabilizing unit stabilizing the power and including a composite body including a capacitor and a coil and having a hexahedral shape, the capacitor including a plurality of dielectric layers, internal electrodes disposed to face each other with a respective dielectric layer interposed between the internal electrodes, and capacitor electrodes electrically connected to the internal electrodes, and the coil being wound to encompass the capacitor and being buried in a magnetic material portion; and an output terminal portion supplying the stabilized power.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view illustrating a driving power supply system supplying driving power to a predetermined terminal requiring driving power through a battery and a power management unit;

FIG. 2 is a view illustrating a layout pattern of a driving power supply system;

FIG. 3 is a circuit diagram of a composite electronic component according to an exemplary embodiment of the present disclosure;

FIG. 4 is a view illustrating a layout pattern of a driving power supply system using a composite electronic component according to an exemplary embodiment of the present disclosure;

FIG. 5 is a perspective view schematically illustrating a composite electronic component according to an exemplary embodiment of the present disclosure;

FIG. 6 is a cross-sectional view of the composite electronic component of FIG. 5;

FIG. 7 is a schematic perspective view illustrating a multilayer ceramic capacitor according to an exemplary embodiment of the present disclosure;

FIG. 8 is a schematic cross-sectional view of the multilayer ceramic capacitor taken along line C-C′ of FIG. 7;

FIG. 9 is a view illustrating an internal pattern of a multilayer ceramic capacitor according to an exemplary embodiment of the present disclosure;

FIG. 10 is a bottom view of the composite electronic component illustrated in FIG. 5;

FIG. 11 is a view illustrating a land pattern in which a composite electronic component according to an exemplary embodiment of the present disclosure is mounted;

FIG. 12 is a perspective view schematically illustrating a composite electronic component according to another exemplary embodiment of the present disclosure; and

FIG. 13 is a cross-sectional view of the composite electronic component of FIG. 12.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

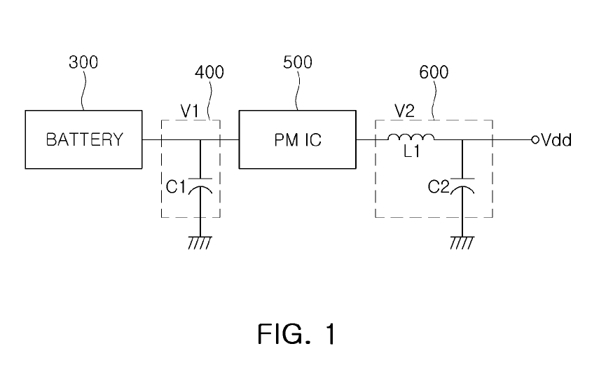

FIG. 1 is a view illustrating a driving power supply system supplying driving power to a predetermined terminal requiring driving power through a battery and a power management unit.

Referring to FIG. 1, the driving power supply system may include a battery 300, a first power stabilizing unit 400, a power management unit 500, and a second power stabilizing unit 600.

The battery 300 may supply power to the power management unit 500. Here, the power supplied to the power management unit 500 by the battery 300 will be defined as a first power.

The first power stabilizing unit 400 may stabilize the first power V₁ and supply the stabilized first power to the power management unit. In detail, the first power stabilizing unit 400 may include a capacitor C₁ located between a connection terminal between the battery 300 and the power management unit 500 and a ground. The capacitor C₁ may decrease noise included in the first power.

In addition, the capacitor C₁ may be charged with electric charges. In addition, in the case in which the power management unit 500 instantaneously consumes a large amount of current, the capacitor C₁ may discharge the electric charges charged therein, thereby suppressing a voltage variation in the power management unit 500.

The capacitor C₁ may be a high capacitance capacitor.

The power management unit 500 may serve to convert power input to an electronic apparatus into power appropriate for the electronic apparatus and may distribute, charge, and control the power. Therefore, the power management unit 500 may generally include a direct current (DC) to DC converter.

In addition, the power management unit 500 may be implemented by a power management integrated circuit (PMIC).

The power management unit 500 may convert the first power V₁ into a second power V₂. The second power V₂ may be required by a predetermined device connected to an output terminal of the power management unit 500 to receive driving power from the power management unit 500.

The second power stabilizing unit 600 may stabilize the second power V₂ and transfer the stabilized second power to an output terminal V_{dd}. The predetermined device receiving the driving power from the power management unit 500 may be connected to the output terminal V_{dd}.

In detail, the second power stabilizing unit 600 may include an inductor L₁ connected between the power management unit 500 and the output terminal V_{dd} in series. In addition, the second power stabilizing unit 600 may include a capacitor C₂ disposed between a connection terminal between the power management unit 500 and the terminal V_{dd} and a ground.

The second power stabilizing unit 600 may decrease noise included in the second power V₂.

In addition, the second power stabilizing unit 600 may stably supply the power to the output terminal V_{dd}.

The inductor L₁ may be a power inductor used for a large amount of current.

In addition, the capacitor C₂ may be a high capacitance capacitor.

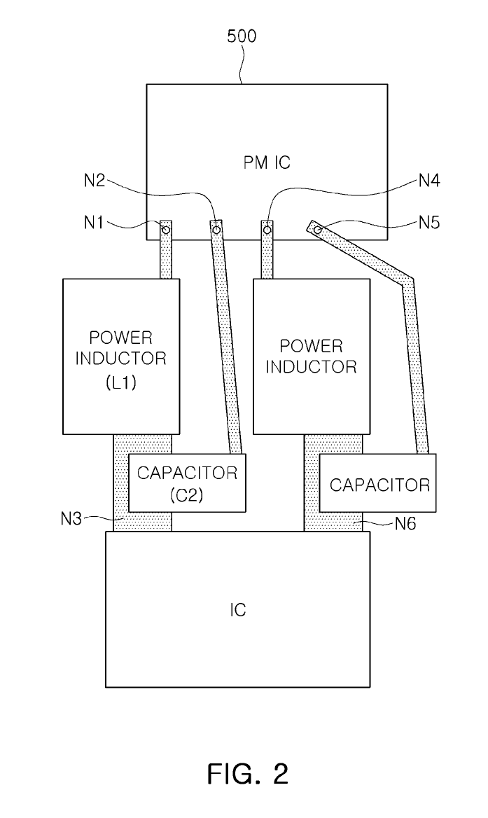

FIG. 2 is a view illustrating a layout pattern of the driving power supply system.

FIG. 2 illustrates layout patterns of the power management unit 500, the power inductor L₁, and the second capacitor C₂.

Generally, the power management unit (PMIC) 500 may include several to several tens of DC to DC converters. In addition, in order to implement a function of the DC to DC converter, a respective DC to DC converter may be required to include a power inductor and a high capacitance capacitor.

Referring to FIG. 2, the power management unit 500 may have predetermined terminals N1 and N2. The power management unit 500 may receive power from the battery and convert the power by using the DC to DC converter. In addition, the power management unit 500 may supply the converted power through the first terminal N1. The second terminal N2 may be a ground terminal.

Here, the first power inductor L₁ and the second capacitor C₂ may receive power from the first terminal N1, stabilize the power, and supply driving power through a third terminal N3. Therefore, the first power inductor L₁ and the second capacitor C₂ may serve as the second power stabilizing unit.

Since fourth to sixth terminals N4 to N6 illustrated in FIG. 2 perform the same functions as those of the first to third terminals N1 to N3, a detailed description thereof will be omitted.

In designing a pattern of the driving power supply system, disposing the power management unit, the power inductor, and the high capacitance capacitor so as to be as close to each other as possible is an important consideration. In addition, it may be required to design a wiring of a power line so as to be relatively short and thick.

The reason may be that such requirements need to satisfy a relatively reduced area of a component and suppress the generation of noise.

In the case in which the number of output terminals of the power management unit 500 is relatively small, a problem does not occur in disposing the power inductor and the high capacitance capacitor so as to be close to each other. However, in the case in which several output terminals of the power management unit 500 need to be used, the power inductor and the high capacitance capacitor may not be normally disposed due to density of the component. In addition, a problem in which the power inductor and the high capacitance capacitor are disposed in a non-optimal state depending on a priority of power may occur.

For example, since sizes of the power inductor and the high capacitance capacitor are relatively large, a case in which a power line and a signal line are inevitably elongated at the time of actually disposing the power inductor and the high capacitance capacitor may occur.

In the case in which the power inductor and the high capacitance capacitor are disposed in a non-optimal state, the power line and an interval between the power inductor and the high capacitance capacitor may be relatively great, such that noise may occur. Such noise may have a negative influence on the driving power supply system.

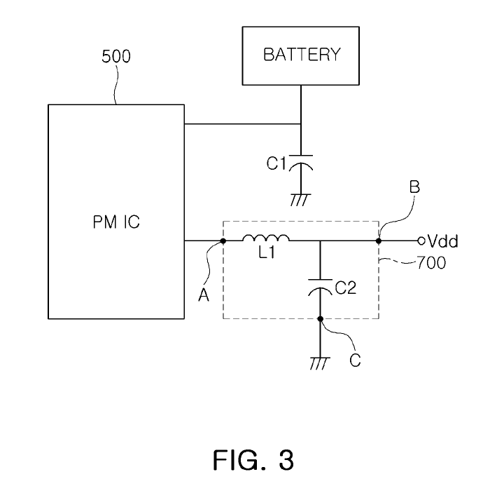

FIG. 3 is a circuit diagram of a composite electronic component according to an exemplary embodiment of the present disclosure.

Referring to FIG. 3, a composite electronic component 700 may include an input terminal portion A (input terminal), a power stabilizing unit, an output terminal portion B (output terminal), and a ground terminal portion C (ground terminal).

The power stabilizing unit may include a power inductor L₁ and a second capacitor C₂.

The composite electronic component 700 may perform a function of the second power stabilizing unit described above.

The input terminal portion A may receive power converted by the power management unit 500.

The power stabilizing unit may stabilize the power supplied through the input terminal portion A.

The output terminal portion B may supply the stabilized power to an output terminal V_{dd}.

The ground terminal portion C may connect the power stabilizing unit to a ground.

Meanwhile, the power stabilizing unit may include the power inductor L₁ connected between the input terminal portion A and the output terminal portion B, and the second capacitor C₂ connected between the ground terminal portion C and the output terminal portion.

Referring to FIG. 3, the power inductor L₁ and the second capacitor C_{z} share the output terminal portion B with each other, such that an interval between the power inductor L₁ and the second capacitor C₂ may be decreased.

As described above, the composite electronic component 700 may be formed by implementing the power inductor and the high capacitance capacitor provided with an output power terminal of the power management unit 500, as a single component. Therefore, the composite electronic component 700 may improve a degree of integration of a device.

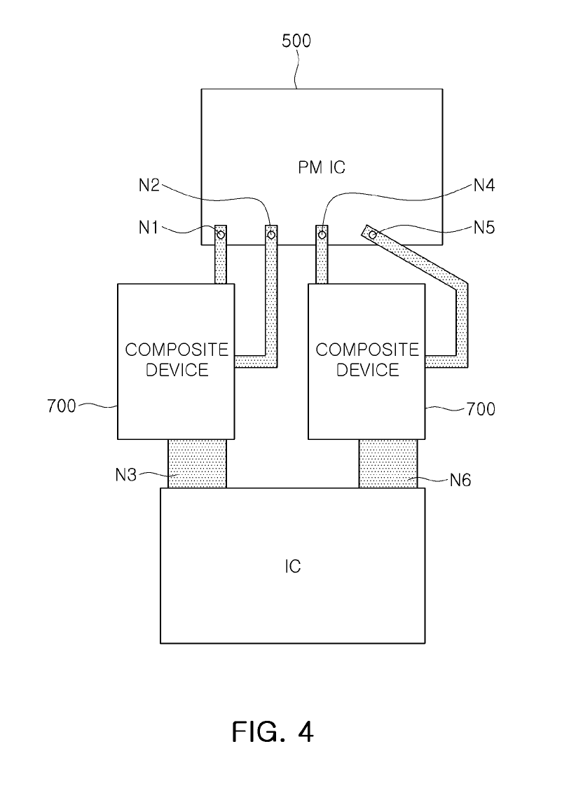

FIG. 4 is a view illustrating a layout pattern of a driving power supply system using a composite electronic component according to an exemplary embodiment of the present disclosure is disposed.

Referring to FIG. 4, it may be confirmed that the second capacitor C₂ and the power inductor L₁ illustrated in FIG. 2 are replaced with a composite electronic component according to an exemplary embodiment of the present disclosure.

As described above, the composite electronic component may serve as the second power stabilizing unit.

In addition, the second capacitor C₂ and the power inductor L₁ may be replaced with a composite electronic component according to an exemplary embodiment of the present disclosure, such that a length of a wiring may be significantly decreased. In addition, the number of disposed devices is decreased, whereby the devices may be optimally disposed.

For example, according to an exemplary embodiment of the present disclosure, the power management unit, the power inductor, and the high capacitance capacitor may be disposed to be as close to each other as possible, and the wiring of the power line may be designed to be relatively short and thick.

Meanwhile, electronic apparatus manufacturers have made an effort to decrease a size of a printed circuit board (PCB) included in an electronic apparatus in order to satisfy consumer's demands. Therefore, it has been demanded to increase a degree of integration of ICs mounted on the PCB. As in the composite electronic component according to an exemplary embodiment of the present disclosure, a plurality of devices are implemented as a single composite component, whereby this demand may be satisfied.

Further, according to an exemplary embodiment of the present disclosure, two components (second capacitor and power inductor) are implemented as a single composite electronic component, whereby an area in which they are mounted on the PCB may be decreased. According to the exemplary embodiment of the present disclosure, an area in which the components are mounted may be decreased as compared with an existing disposition pattern by about 10 to 30%.

Further, according to an exemplary embodiment of the present disclosure, the power management unit 500 may supply driving power to the IC receiving the driving power through a relatively smallest wiring.

Composite Electronic Component

Hereinafter, exemplary embodiments of the present disclosure will be described in detail with reference to the accompanying drawings.

A direction of a hexahedron will be defined in order to clearly describe exemplary embodiments of the present disclosure. L, W and T in the accompanying drawings refer to a length direction, a width direction, and a thickness direction, respectively.

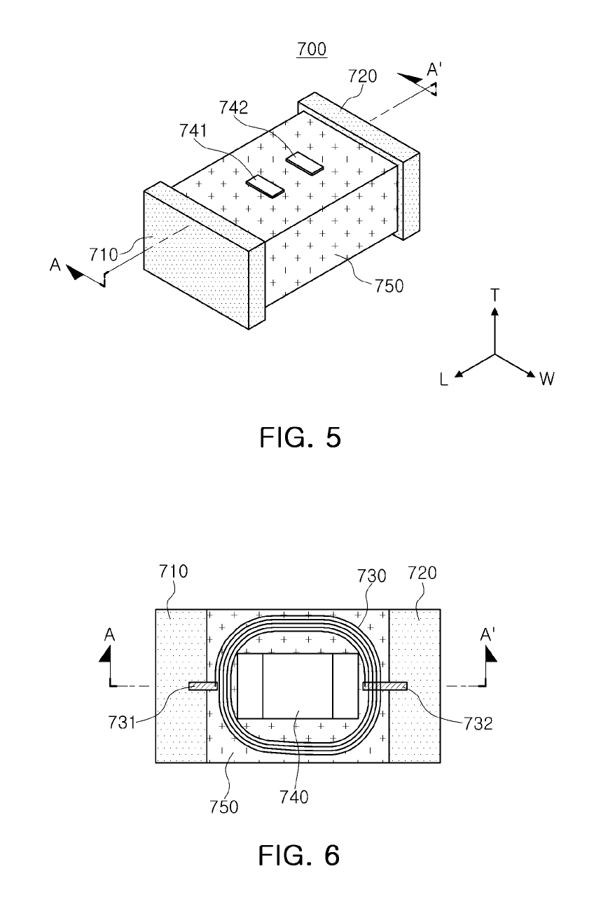

FIG. 5 is a perspective view schematically illustrating a composite electronic component according to an exemplary embodiment of the present disclosure.

FIG. 6 is a cross-sectional view of the composite electronic component of FIG. 5.

Referring to FIGS. 5 and 6, the composite electronic component 700 according to an exemplary embodiment of the present disclosure may include a composite body including a capacitor 740 and a coil 730 and having a hexahedral shape, the capacitor 740 including a plurality of dielectric layers, internal electrodes disposed so as to face each other with each of the dielectric layers interposed therebetween, and capacitor electrodes electrically coupled to the internal electrodes, and the coil 730 being wound to encompass the capacitor and being buried in a magnetic material portion 750.

The composite body may be used as a power stabilizing unit.

In detail, the composite electronic component 700 may include the coil 730 having an air-core portion formed therein and the capacitor 740 disposed in the air-core portion. Here, the air-core portion may refer to a magnetic material region formed between the center of the composite body and the coil 730.

In addition, the composite electronic component 700 according to an exemplary embodiment of the present disclosure may include an input terminal portion 710 formed on a first end surface of the composite body in a length direction thereof and connected to one end of the coil 730. The input terminal portion 710 may receive power converted by the power management unit.

In addition, the composite electronic component 700 according to an exemplary embodiment of the present disclosure may include an output terminal portion 720 formed on a second end surface of the composite body in a length direction thereof and connected to the other end of the coil 730. The output terminal portion 720 may supply stabilized power.

In the exemplary embodiment of the present disclosure, the composite body having the hexahedral shape may have first and second main surfaces opposing each other in a thickness direction of the composite body, first and second end surfaces opposing each other in a length direction thereof, and side surfaces opposing each other in a width direction thereof and connecting the first and second main surfaces to each other.

For convenience of explanation, the first and second main surfaces refer to upper and lower surfaces of the composite body in the thickness direction, both side surfaces refer to first and second side surfaces of the composite body opposing each other in the width direction, and both end surfaces refer to first and second end surfaces of the composite body in the length direction thereof.

In addition, with reference to FIG. 5, the first end surface refers to an end surface on which the input terminal portion 710 is formed, and the second end surface refers to an end surface on which the output terminal portion 720 is formed.

Meanwhile, a shape of the composite body is not particularly limited, but may be a hexahedral shape as shown. The composite body having the hexahedral shape may include the capacitor 740 and the coil 730 buried in the magnetic material portion. A method of forming the composite body is not particularly limited.

Hereinafter, the capacitor 740 included in the composite body will be described in detail.

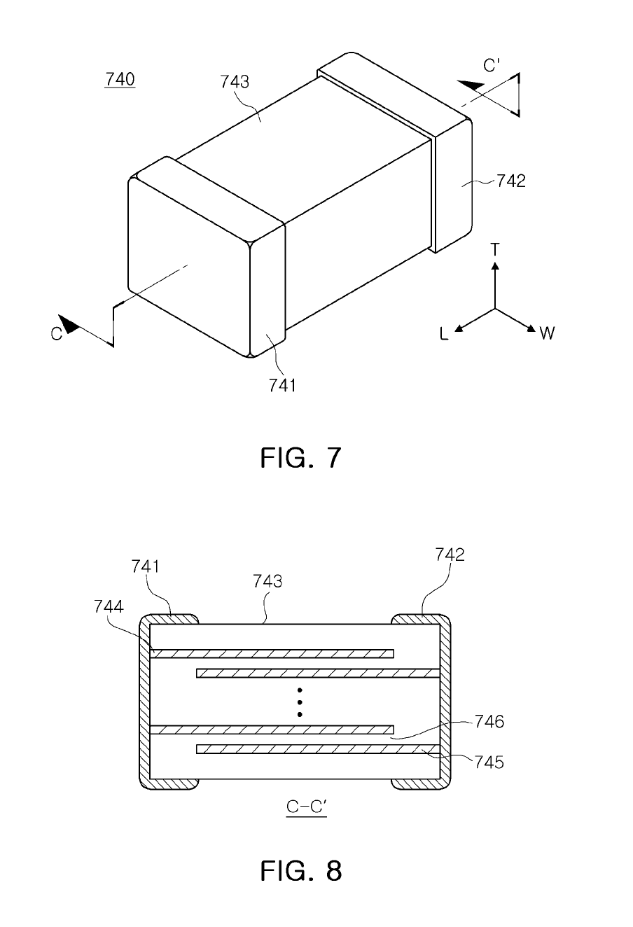

FIG. 7 is a schematic perspective view illustrating a multilayer ceramic capacitor according to an exemplary embodiment of the present disclosure.

FIG. 8 is a schematic cross-sectional view of the multilayer ceramic capacitor taken along line C-C′ of FIG. 7.

Referring to FIGS. 7 and 8, the multilayer ceramic capacitor according to the exemplary embodiment of the present disclosure may include a ceramic body 743 having a plurality of dielectric layers stacked therein, a plurality of internal electrodes 744 and 745 formed on the dielectric layers, and capacitor electrodes 741 and 742 formed on end surfaces of the ceramic body 743.

A shape of the ceramic body 743 is not particularly limited, but may be generally a rectangular parallelepiped shape.

The ceramic body 743 may be formed by stacking the plurality of dielectric layers. The plurality of dielectric layers forming the ceramic body 743 may be in a sintered state, and adjacent dielectric layers may be integrated with each other so that boundaries therebetween are not readily apparent without a scanning electron microscope (SEM).

One dielectric layer may be formed by sintering a ceramic green sheet containing a ceramic powder.

The ceramic powder is not particularly limited, but may be any ceramic power that is generally used in the related art. The ceramic powder may include, for example, a BaTiO₃ based ceramic powder, but is not limited thereto. An example of the BaTiO₃ ceramic powder may include (Ba₁₋ₓCaₓ)TiO₃, Ba(Ti_{1-y}Ca_{y})O₃, (Ba₁₋ₓCaₓ) (Ti_{1-y}Zr_{y})O₃, Ba (Ti_{1-y}Zr_{y})O₃, or the like, in which Ca, Zr, or the like, is partially dissolved in BaTiO₃, but is not limited thereto.

In addition, the ceramic green sheet may contain a transition metal oxide or carbide, a rare earth element, magnesium (Mg), aluminum (Al), or the like, together with the ceramic powder.

A thickness of one dielectric layer may be appropriately changed in accordance with a capacitance design of the multilayer ceramic capacitor.

The ceramic body 743 may include the plurality of internal electrodes 744 and 745 formed therein. The internal electrodes 744 and 745 may be formed on the dielectric layer to then be sintered so as to have a dielectric layer interposed therebetween in the ceramic body 743.

The internal electrodes may include first and second internal electrodes 744 and 745 having different polarities and formed in pair and may be disposed so as to face each other in a stacked direction of the dielectric layers. Distal ends of the first and second internal electrodes 744 and 745 may be alternately exposed to both end surfaces of the ceramic body 743 opposing each other in the length direction.

Thicknesses of the internal electrodes 744 and 745 may be appropriately determined depending on the use thereof, or the like.

The capacitor electrodes 741 and 742 may be formed on the end surfaces of the ceramic body 743 in the length direction thereof and be electrically connected to the internal electrodes 744 and 745, respectively. In more detail, the capacitor electrodes may include a first capacitor electrode 741 electrically connected to the first internal electrodes 744 exposed to one end surface of the ceramic body 743 and a second capacitor electrode 742 electrically connected to the second internal electrodes 745 exposed to the other end surface of the ceramic body 743.

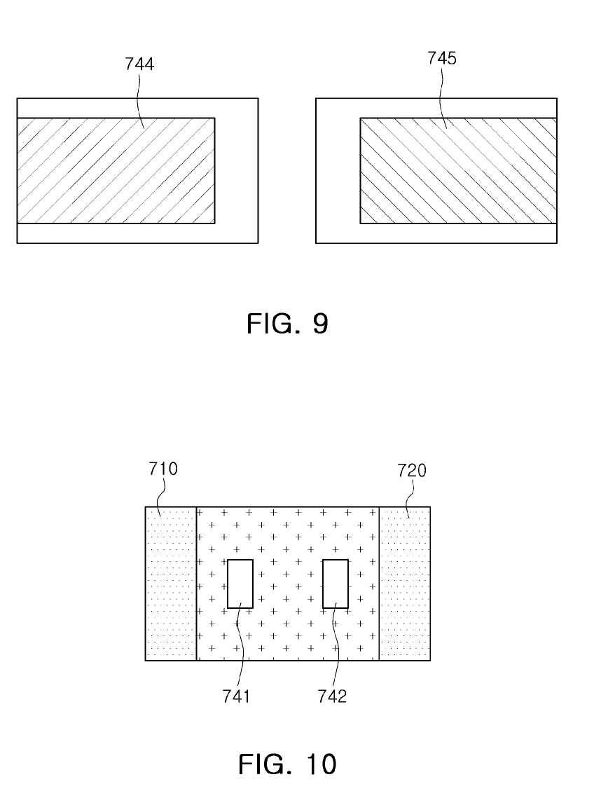

FIG. 9 is a view illustrating an internal pattern of the multilayer ceramic capacitor according to an exemplary embodiment of the present disclosure.

The internal patterns illustrated in FIG. 9 are stacked, such that the multilayer ceramic capacitor according to an exemplary embodiment of the present disclosure may be formed. In addition, a form of the internal pattern is not limited to a form illustrated in FIG. 9, but may be variously changed.

The capacitor may serve to control a voltage supplied from a power management integrated circuit (PMIC).

Hereinafter, the coil 730 of the composite body will be described in detail.

Referring back to FIG. 6, the coil 730 may be wound so as to encompass the first side surface, the first end surface, the second side surface, and the second end surface of the capacitor.

In addition, the coil 730 may be wound to be parallel to a plane defined by the length direction and the width direction of the composite electronic component.

In addition, a winding center of the coil 730 may be formed on the plane defined by the length direction and the width direction of the composite electronic component.

Meanwhile, according to an exemplary embodiment of the present disclosure, one end of the coil 730 may be electrically connected to the input terminal portion 710. Here, a connecting part 731 may be used in order to electrically connect one end of the coil 730 and the input terminal portion 710 to each other.

In addition, the other end of the coil 730 may be electrically connected to the output terminal portion 720. Here, a connecting part 732 may be used in order to electrically connect the other end of the coil 730 and the output terminal portion 720 to each other.

FIG. 10 is a bottom view of the composite electronic component illustrated in FIG. 5.

Referring to FIGS. 5 and 10, the capacitor electrodes 741 and 742 may protrude from both of upper and lower surfaces of a hexahedral shape.

Alternatively, the capacitor electrodes 741 and 742 may protrude from at least one of the upper and lower surfaces of the hexahedral shape.

One of the plurality of capacitor electrodes 741 and 742 may be used to be connected to a ground. Here, the remaining one of the plurality of capacitor electrodes 741 and 742 may be connected to an output pattern. Therefore, one of the capacitor electrodes may be a ground terminal portion.

Meanwhile, referring to FIGS. 5 and 10, the capacitor may be disposed so that the protruded capacitor electrodes 741 and 742 may be elongated in the width direction thereof.

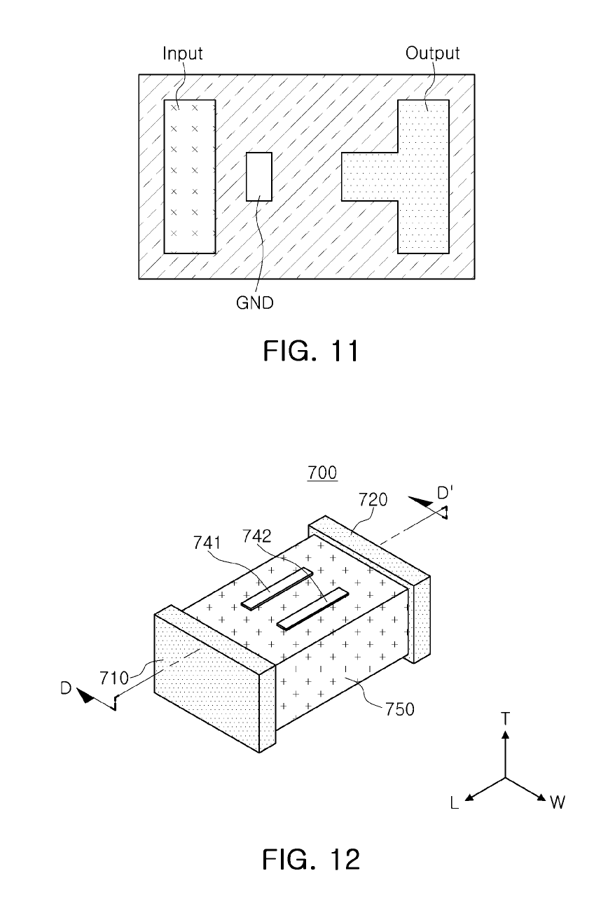

FIG. 11 is a view illustrating a land pattern in which a composite electronic component according to an exemplary embodiment of the present disclosure is mounted.

For example, the composite electronic component illustrated in FIG. 5 may be mounted on the land pattern illustrated in FIG. 11.

The land pattern may include an input pattern Input, a ground pattern GND, and an output pattern Output.

Therefore, the input terminal portion 710 of the composite electronic component may be connected to the input pattern Input, the ground terminal portion thereof may be connected to the ground pattern GND, and the output terminal portion 720 thereof may be connected to the output pattern Output.

FIG. 12 is a perspective view schematically illustrating a composite electronic component according to another exemplary embodiment of the present disclosure.

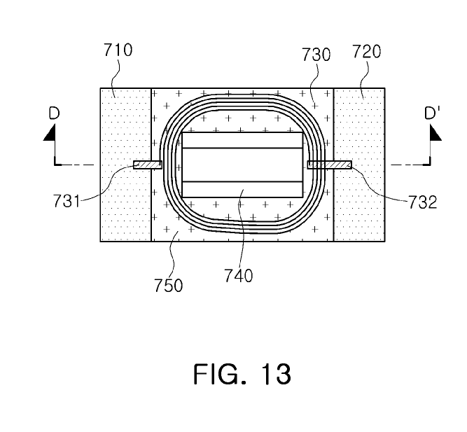

FIG. 13 is a cross-sectional view of the composite electronic component of FIG. 12.

Referring to FIG. 12, in the composite electronic component according to another exemplary embodiment of the present disclosure, the capacitor may be disposed so that protruded capacitor electrodes 741 and 742 may be elongated in the length direction thereof.

In addition, the capacitor may be a low inductance chip capacitor (LICC) type.

Since the composite electronic component according to another exemplary embodiment of the present disclosure has the same features as those of the composite electronic component according to the foregoing exemplary embodiment of the present disclosure described above, except for a form in which the capacitor is disposed, a detailed description thereof will be omitted.

According to exemplary embodiments of the present disclosure, the composite electronic component ale to be mounted in a decreased area in the driving power supply system may be provided.

In addition, according to exemplary embodiments of the present disclosure, the composite electronic component capable of suppressing the generation of noise in the driving power supply system may be provided.

While exemplary embodiments have been shown and described above, it will be apparent to those skilled in the art that modifications and variations could be made without departing from the spirit and scope of the present disclosure as defined by the appended claims.

What is claimed is:

1. A composite electronic component comprising:
an input terminal portion receiving power converted by a power management unit;
a power stabilizing unit stabilizing the power; and
an output terminal portion supplying the stabilized power,
wherein the power stabilizing unit includes:
a coil having an air-core portion; and
a capacitor disposed in the air-core portion.

2. The composite electronic component of claim 1, wherein the coil is wound to encompass a first side surface, a first end surface, a second side surface, and a second end surface of the capacitor.

3. The composite electronic component of claim 1, wherein the coil is wound to be parallel to a plane defined by a length direction and a width direction of the composite electronic component.

4. The composite electronic component of claim 1, wherein a winding center of the coil is formed on a plane defined by a length direction and a width direction of the composite electronic component.

5. The composite electronic component of claim 1, wherein the coil is electrically connected to the input terminal portion and the output terminal portion.

6. The composite electronic component of claim 1, wherein the capacitor comprises:
a plurality of dielectric layers;
a plurality of internal electrodes disposed to face each other so as to have a respective dielectric layer interposed between the plurality of internal electrodes; and
capacitor electrodes electrically connected to the internal electrodes.

7. The composite electronic component of claim 6, wherein the capacitor electrodes are elongated in the width direction.

8. The composite electronic component of claim 6, wherein the capacitor electrodes are elongated in the length direction.

9. The composite electronic component of claim 1, wherein the power stabilizing unit decreases noise of the power.

10. A composite electronic component comprising:
a composite body including a capacitor and a coil and having a hexahedral shape, the capacitor including a plurality of dielectric layers, internal electrodes disposed to face each other with a respective dielectric layer interposed between the internal electrodes, and capacitor electrodes electrically connected to the internal electrodes, and the coil being wound to encompass the capacitor and being buried in a magnetic material portion;
an input terminal portion formed on a first end surface of the composite body and connected to one end of the coil; and
an output terminal portion formed on a second end surface of the composite body and connected to the other end of the coil.

11. The composite electronic component of claim 10, wherein the capacitor electrodes protrude from at least one of upper and lower surfaces of the composite body having the hexahedral shape.

12. A composite electronic component comprising:
an input terminal portion receiving power converted by a power management unit;
a power stabilizing unit stabilizing the power and including a composite body including a capacitor and a coil and having a hexahedral shape, the capacitor including a plurality of dielectric layers, internal electrodes disposed to face each other with a respective dielectric layer interposed between the internal electrodes, and capacitor electrodes electrically connected to the internal electrodes, and the coil being wound to encompass the capacitor and being buried in a magnetic material portion; and
an output terminal portion supplying the stabilized power.
